(19) United States
(12) Patent Application Publication
(10) Pub. No.: US 2012/0268993 A1
(43) Pub. Date: Oct. 25, 2012

(54) SEMICONDUCTOR MEMORY DEVICE

(76) Inventor: Jin Su PARK, Daegu (KR)

(21) Appl. No.: 13/453,641

(22) Filed: Apr. 23, 2012

(30) Foreign Application Priority Data
Apr. 21, 2011 (KR) 10-2011-0037167

(51) Int. Cl. G11C 16/04

(52) U.S. Cl. 365/185.11

(57) ABSTRACT

A semiconductor memory device includes first and second memory planes that each include a plurality of memory blocks, a first page buffer group coupled to the memory blocks of the first memory plane through first bit lines and configured to perform a read operation and a program operation, a second page buffer group coupled to the memory blocks of the second memory plane through second bit lines and configured to perform the read operation and the program operation, a coupling circuit configured to couple the first bit lines of the first memory planes and the second bit lines of the second memory planes, respectively, in response to a coupling signal, and a control circuit configured to generate the coupling signal for controlling the coupling circuit in a copyback operation of data, read from a source page of the first memory plane, in a target page of the second memory plane.

### CROSS-REFERENCE TO RELATED APPLICATION

Priority to Korean patent application number 10-2011-0037167 filed on Apr. 21, 2011, the entire disclosure of which is incorporated by reference herein, is claimed.

### BACKGROUND

Exemplary embodiments relate to a semiconductor memory device and, more particularly, to a semiconductor memory device for storing data, read from a source page in a target page.

In general, memory cells for storing data are classified to form the memory block. Memory cells coupled to a word line in the memory block form a page. Furthermore, even-numbered memory cells of the memory cells coupled to the word line may form an even page, and odd-numbered memory cells thereof may form an odd page. The memory blocks are classified to form the memory plane.

Meanwhile, memory blocks included in a memory plane are operated by a peripheral circuit (e.g., a page buffer). Memory blocks included in different memory planes are operated by different peripheral circuits because the memory planes independently operate.

For this reason, while performing a copyback operation for storing data, read from a page (e.g., a source page) of a memory plane, in another page (e.g., a target page) of the memory plane, a semiconductor memory device may not perform a copyback operation of reading data from a source page of one memory plane and storing the read data in a target page of the other memory plane. The data may be read and stored between different memory planes through an external memory controller. However, it may be performed through complicated operations.

### BRIEF SUMMARY

Exemplary embodiments relate to an increase in operational efficiency by reading data from a source page of one memory plane and storing the read data in a target page of the other memory plane, through a copyback operation.

A semiconductor memory device according to an aspect of the present disclosure includes first and second memory planes that each include a plurality of memory blocks, a first page buffer group coupled to the memory blocks of the first memory plane through first bit lines and configured to perform a read operation and a program operation, a second page buffer group coupled to the memory blocks of the second memory plane through second bit lines and configured to perform the read operation and the program operation, a coupling circuit configured to couple the first bit lines of the first memory plane and the second bit lines of the second memory plane, respectively, in response to a coupling signal, and a control circuit configured to generate the coupling signal for controlling the coupling circuit in a copyback operation of storing data, read from a source page of the first memory plane, in a target page of the second memory plane.

The first page buffer group may perform the read operation of reading the data from the source page of the first memory plane, the coupling circuit may transfer the data of the source page, stored in the first page buffer group, to the second page buffer group, and the second page buffer group may perform the program operation of storing the data in the target page of the second memory plane.

The coupling circuit may couple the first bit lines and the second bit lines so that the second page buffer group is coupled to the first memory plane through the first bit lines, the second page buffer group may perform the read operation of reading the data from the source page of the first memory plane, and the second page buffer group may perform the program operation of storing the data, read from the source page of the first memory plane, in the target page of the second memory plane.

The control circuit may control the coupling circuit so that the first bit lines are disconnected from the second bit lines when the second page buffer group may perform the program operation.

The second page buffer group may precharge the first bit lines of the first memory plane through the second bit lines in order to read the data from the source page of the first memory plane.

The first page buffer group may perform the read operation of reading the data from the source page of the first memory plane, the coupling circuit may couple the first bit lines and the second bit lines so that the first page buffer group is coupled to the second memory plane through the second bit lines, and the first page buffer group may perform the program operation of storing the data, read from the source page of the first memory plane, in the target page of the second memory plane.

After the data read from the source page is stored in the first page buffer group, the control circuit may generate the coupling signal so that the coupling circuit couples the first bit lines of the first memory planes and the second bit lines of the second memory planes.

### BRIEF DESCRIPTION OF THE DRAWINGS

FIG. 1 is a block diagram of a semiconductor memory device according to an exemplary embodiment of this disclosure;

FIG. 2 is a circuit diagram of a memory block shown in FIG. 1;

FIG. 3 is a circuit diagram of a coupling circuit shown in FIG. 1; and

FIGS. 4A to 4C are diagrams illustrating an operating method of the semiconductor memory device according to an exemplary embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

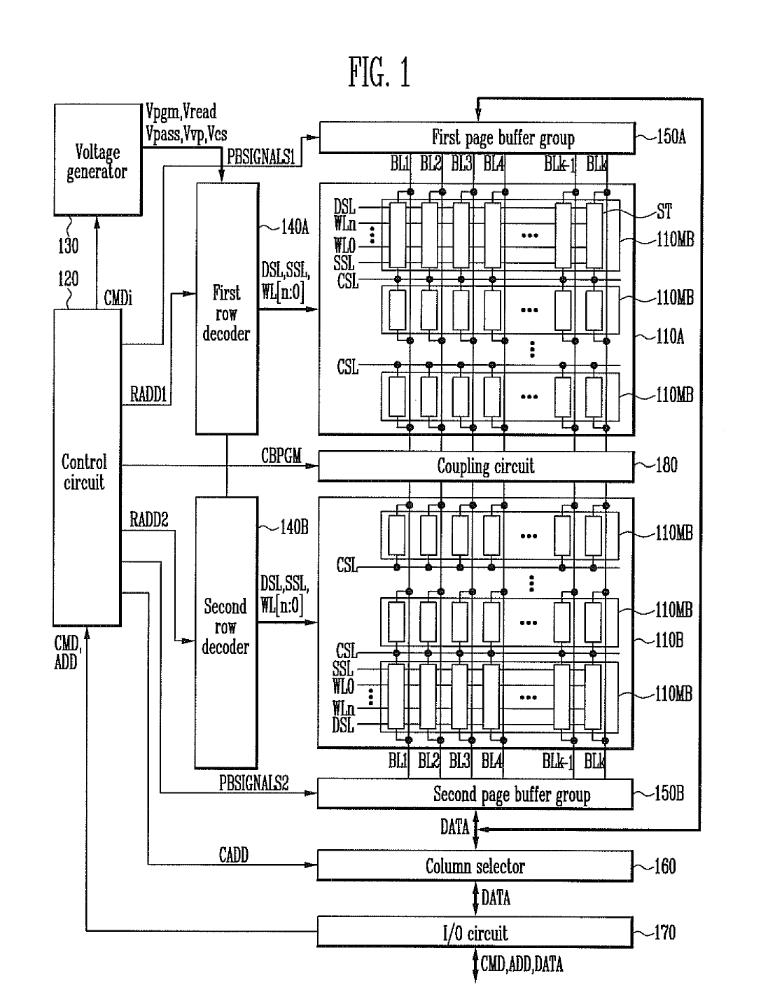

FIG. 1 is a block diagram of a semiconductor memory device according to an exemplary embodiment of this disclosure.

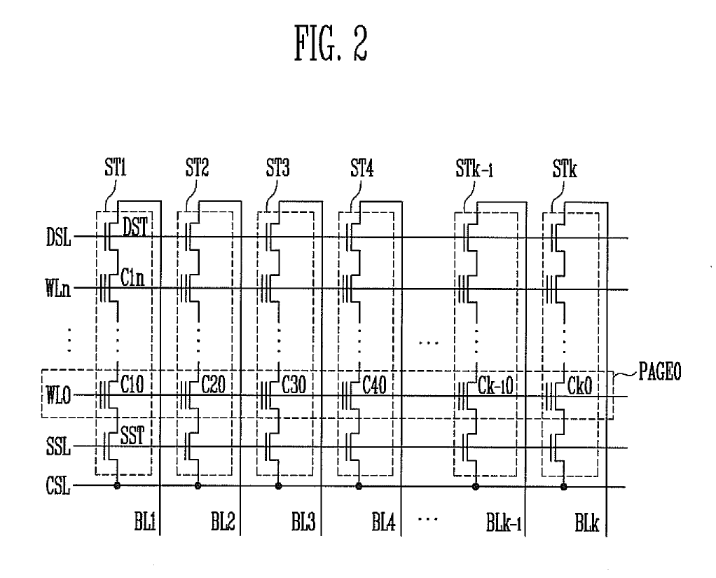

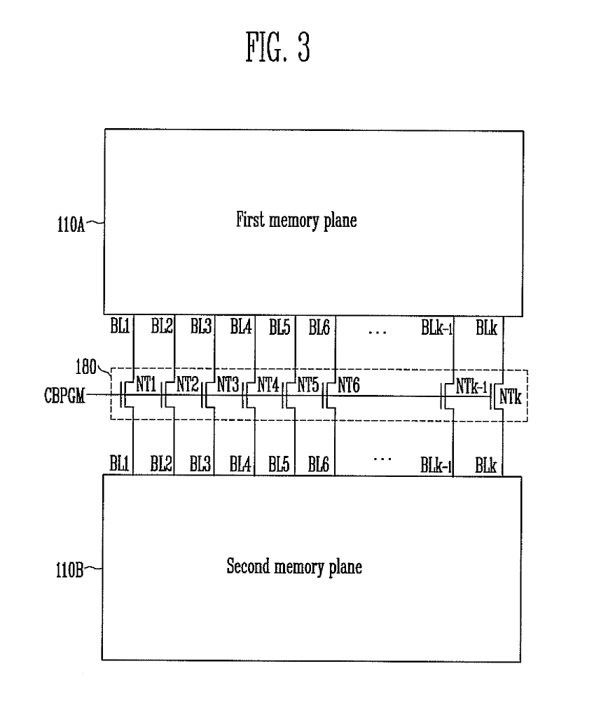

FIG. 2 is a circuit diagram of a memory block shown in FIG. 1. FIG. 3 is a circuit diagram of a coupling circuit shown in FIG. 1.

Referring to FIG. 1, the semiconductor memory device includes a plurality of memory areas (e.g., planes) 110A and 110B, an operation circuit group (130, 140A, 140B, 150A, 150B, 160, and 170) configured to perform the program operation or the read operation of memory cells, a coupling circuit 180, and a control circuit 120 configured to control the operation circuit group (130, 140A, 140B, 150A, 150B, 160, and 170) and the coupling circuit 180. For example, in a NAND flash memory device, the operation circuit group includes a voltage supply circuit (130, 140A, and 140B), a page buffer group (150A and 150B), a column selector 160, and an I/O circuit 170.

Each of the memory planes 110A and 110B includes a plurality of memory blocks 110MB.

Referring to FIG. 2, each of the memory blocks 110MB includes a plurality of strings ST1 to STk coupled between bit lines BL1 to BLk and a common source line CSL. More particularly, the strings ST1 to STk are coupled to the respective bit lines BL1 to BLk and in common coupled to the common source line CSL. Each (e.g., ST1) of the strings includes a source select transistor SST having a source coupled to the common source line CSL, a plurality of memory cells C10 to C1n, and a drain select transistor DST having a drain coupled to the bit line BL1. The gate of the source select transistor SST is coupled to a source select line SSL, the gates of the memory cells C10 to din are coupled to respective word lines WL0 to WLn, and the gate of the drain select transistor DST is coupled to a drain select line DSL.

In the NAND flash memory device, the memory cells of the memory block may be classified by a group, e.g., the physical page or the logical page.

For example, memory cells C10 to Ck0 coupled to a word line (e.g., WL0) may form a physical page PAGED. Furthermore, odd-numbered memory cells C10, C30 to Ck−10 coupled to the word line WL0 may form an odd physical page, and even-numbered memory cells C20, C40 to Ck0 coupled to the word line WL0 may form an even physical page. Meanwhile, if 2-bit data is stored in a memory cell, the physical page PAGED includes a logical LSB page for storing LSB data of 2 bits and a logical MSB page for storing MSB data of 2 bits. The page is a basic unit for a program operation or a read operation.

Referring back to FIG. 1, the control circuit 120 generates an internal command signal CMDi for a program operation, a read operation, or an erase operation in response to an external command signal CMD and also generates control signals PBSIGNALS1 and PBSIGNALS2 for controlling the page buffers of the first and the second page buffer groups 150A and 150B depending on a type of an operation. Furthermore, the control circuit 120 generates first and second row address signals RADD1 and RADD2 and a column address signal CADD in response to an address signal ADD.

In this disclosure, the control circuit 120 controls the operation circuit group (130, 140A, 140B, 150A, 150B, 160, and 170) to perform a copyback program operation of reading data from a selected page of the memory block 110MB included in the memory plane 110A and storing the read data in a selected page of the memory block 110MB included in the memory plane 110B.

The voltage supply circuit (130, 140A, and 140B) supplies operating voltages (e.g., Vpgm, Vread, Vpass, Vvp, and Vcs) for the program operation or the read operation of the memory cells to the drain select line DSL, the word lines WL0 to WLn, the source select line SSL, and the common source line CSL of a selected memory block in response to the command signal CMDi. The voltage supply circuit includes a voltage generator 130 and first and second row decoders 140A and 1408.

The voltage generator 130 generates the operating voltages for the program operation or the read operation of the memory cells to global lines in response to the command signal CMDi. For example, in a program operation, the voltage generator 130 may supply the global lines with a program voltage Vpgm to be supplied to selected memory cells, a pass voltage Vpass to be supplied to unselected memory cells, and a voltage Vcs to be supplied to the common source line CSL. In a program verification operation, the voltage generator 130 may supply the global lines with a program verification voltage Vvp to be supplied to selected memory cells, the pass voltage Vpass to be supplied to unselected memory cells, and the voltage Vcs to be supplied to the common source line CSL. In a read operation, the voltage generator 130 may supply the global lines with a read voltage Vread to be supplied to selected memory cells, the pass voltage Vpass to be supplied to unselected memory cells, and the voltage Vcs to be supplied to the common source line CSL.

In order to transfer the operating voltages generated from the voltage generator 130 to the local lines DSL, WL0 to WLn, and SSL of a memory block selected from the memory blocks 110MB of the first memory plane 110A, the first row decoder 140A couples the global lines and the local lines DSL, WL0 to WLn, and SSL of the selected memory block in response to the first row address signals RADD1 of the control circuit 120. Thus, the program voltage Vpgm, the program verification voltage Vvp, or the read voltage Vread is supplied from the voltage generator 130 to a local word line (e.g., WL0), coupled to a selected memory cell (e.g., C10), via a global word line. Furthermore, the pass voltage Vpass is supplied from the voltage generator 130 to local word lines (e.g., WL1 to WLn), coupled to the remaining memory cells (e.g., C11 to C1n), via global word lines. Accordingly, data is stored in the selected memory cell C10 by the program voltage Vpgm, the threshold voltage of the selected memory cell C10 is detected by the program verification voltage Vvp, or data stored in the selected memory cell C10 is read by the read voltage Vread. The voltage generator 130 and the first row decoder 140A function as the voltage supply circuit of the first memory plane 110A for a program operation, a program verification operation, or a read operation.

In order to transfer the operating voltages generated from the voltage generator 130 to the local lines DSL, WL0 to WLn, and SSL of a memory block selected from among the memory blocks 110MB of the second memory plane 110B, the second row decoder 140B couples the global lines and the local lines DSL, WL0 to WLn, and SSL of the selected memory block in response to the second row address signals RADD2 of the control circuit 120. The voltage generator 130 and the second row decoder 140B function as the voltage supply circuit of the second memory plane 110B.

The first page buffer group 150A includes a plurality of page buffers (not shown) for storing data read from a page of the memory block 110MB or storing data in the page. The page buffers may be coupled to the respective bit lines BL1 to BLk or may be coupled to respective pairs of the bit lines each including an even bit line and an odd bit line. Each of the page buffers controls the voltage of the corresponding bit line on the basis of input data in order to store the input data in the corresponding memory cell or detects the voltage of the bit line in order to verify or read the data of the memory cell, in response to the first control signals PBSIGNALS1 of the control circuit 120.

The second page buffer group 150B has the same construction as the first page buffer group 150A and performs the same function as the first page buffer group 150A in response to the second control signals PBSIGNALS2 of the control circuit 120. More specifically, the second page buffer group 150B controls the voltages of the bit lines BL1 to BLk on the basis of input data in order to store the input data in the memory cells C10 to Ck0 or detects the voltages of the bit lines BL1 to BLk in order to verify or read the data of the memory cells C10 to Ck0, in response to the second control signals PBSIGNALS2 of the control circuit 120.

The column selector 160 selects the page buffers of the page buffer group 150A or 150B in response to the column address signal CADD of the control circuit 120. Data to be stored in memory cells is inputted to a page buffer selected by the column selector 160, or data read from memory cells is outputted from the selected page buffer.

The I/O circuit 170 transfers external data DATA, received from the outside (e.g., a memory controller), to the column selector 160 under the control of the control circuit 120 so that the external data DATA is inputted to the page buffer group 150A or 150B and then stored in memory cells in a program operation. When the column selector 160 sequentially transfers the external data to the page buffers of the page buffer group 150A or 150B, the page buffers stores the external data in their internal latches. Furthermore, in a read operation, the I/O circuit 170 outputs data DATA, received from the page buffers of the page buffer group 150A or 150B via the column selector 160, to the outside (e.g., the memory controller).

The coupling circuit 180 couples the bit lines BL1 to BLk of the first memory plane 110A and the respective bit lines BL1 to BLk of the second memory plane 110B in response to a coupling signal CBPGM generated from the control circuit 120. More specifically, in an operation for storing data, read from a source page of the first memory plane 110A, in a target page of the second memory plane 110B, the coupling circuit 180 couples the bit lines BL1 to BLk of the first memory plane 110A and the respective bit lines BL1 to BLk of the second memory plane 110B in response to the coupling signal CBPGM so that the data read from the source page of the first memory plane 110A and stored in the first page buffer group 150A may be transferred to the second page buffer group 150B of the second memory plane 110B through the bit lines BL1 to BLk of the first memory plane 110A and the bit lines BL1 to BLk of the second memory plane 110B.

After the bit lines BL1 to BLk of the first memory plane 110A and the second memory plane 110B are coupled by the coupling circuit 180, the first page buffer group 110A outputs the data, read from the source page of the first memory plane 110A, to the bit lines BL1 to BLk. The second page buffer group 110B stores the data received through the bit lines BL1 to BLk of the first memory plane 110A and the bit lines BL1 to BLk of the second memory plane 110B and then controls the voltages of the bit lines BL1 to BLk of the second memory plane 110B in order to store the received data in the source page of the second memory plane 110B. For example, a program permission voltage (e.g., a ground voltage) may be supplied to a bit line coupled to a memory cell in which program data (e.g., data ‘0’) is to be stored by the second page buffer group 150B, and a program inhibition voltage (e.g., a power supply voltage) may be supplied to a bit line coupled to a memory cell in which erase data (e.g., data ‘1’) is to be stored by the second page buffer group 150B.

When the coupling circuit 180 disconnects the bit lines BL1 to BLk of the first memory plane 110A from the bit lines BL1 to BLk of the second memory plane 110B, the second page buffer group 150B stores the data in the target page of the second memory plane 110B.

The coupling circuit 180, as shown in FIG. 3, includes switching elements NT1 to NTk coupled to the respective bit lines BL1 to BLk of the first memory plane 110A and the respective bit lines BL1 to BLk of the second memory plane 110B. The switching elements NT1 to NTk are operated in response to the coupling signal CBPGM and each may be formed of an NMOS transistor.

Below is described an operation that the semiconductor memory device according to the embodiment of this disclosure stores data, read from a source page of the second memory plane, in a target page of the first memory plane.

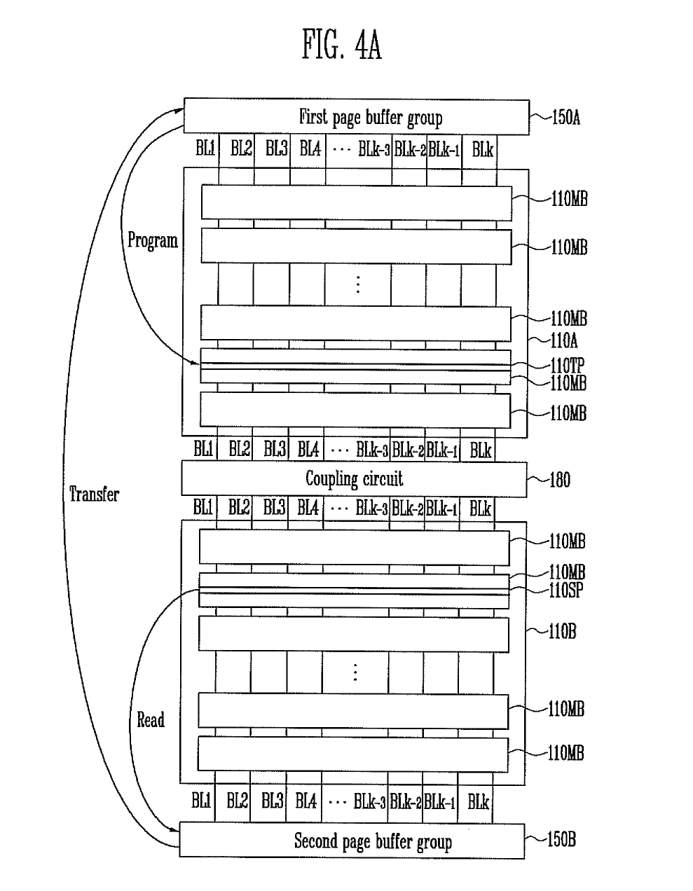

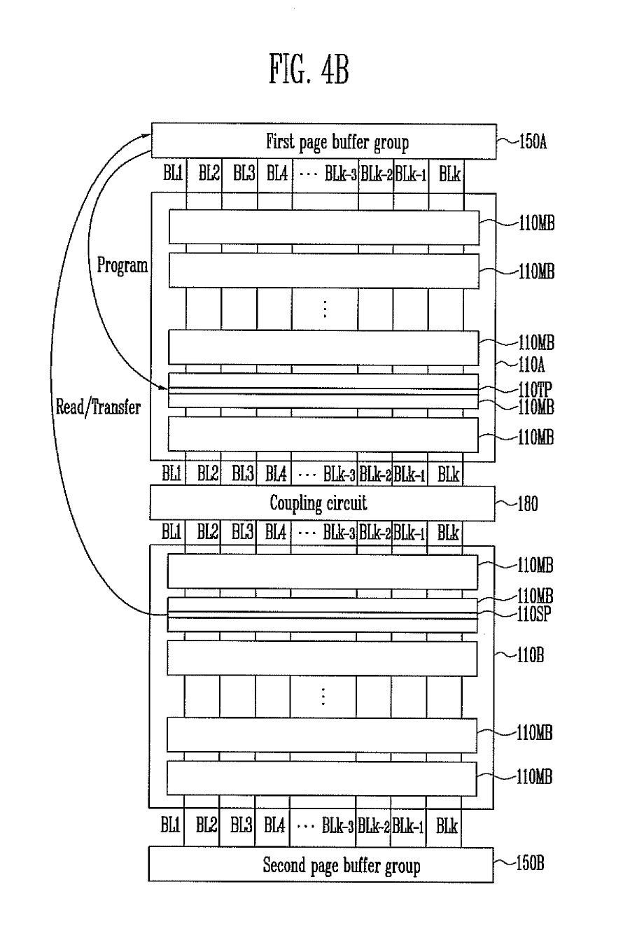

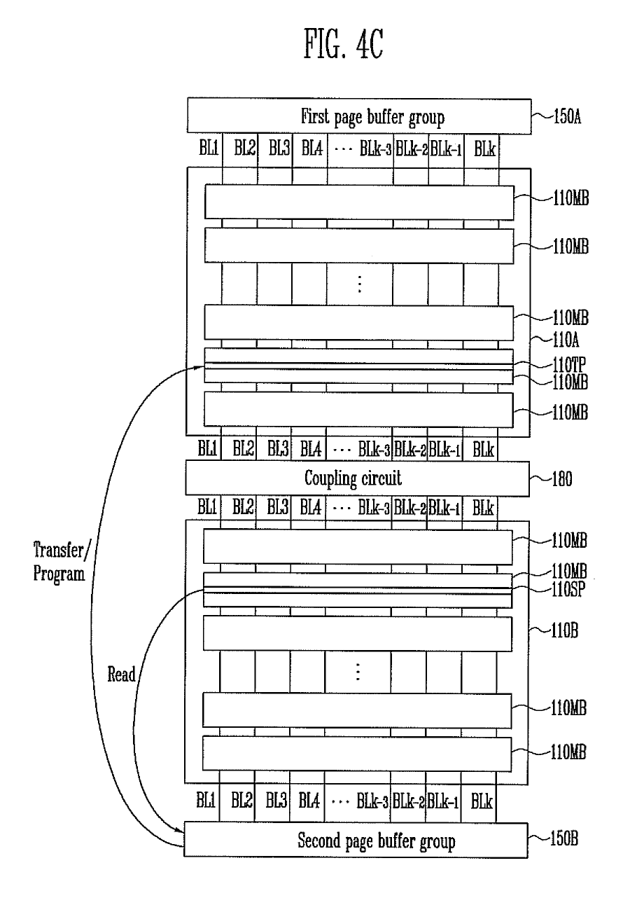

FIGS. 4A to 4C are diagrams illustrating an operating method of the semiconductor memory device according to an exemplary embodiment of this disclosure.

Referring to FIGS. 1 and 4A, a read operation for a source page 110SP is performed. An exemplary read operation is described in detail below. After the bit lines BL1 to BLk of the second memory plane 110B are precharged by the second page buffer group 150B, the voltage supply circuit (130 and 140B) supplies a selected memory block 110MB of the second memory plane 110B with the operating voltages including the read voltage Vread and the pass voltage Vpass. Here, the read voltage Vread is supplied to a word line corresponding to the source page 110SP, and the pass voltage Vpass is supplied to the remaining word lines of the selected memory block 110MB. A voltage (i.e., a precharged voltage) is discharged from bit lines coupled to memory cells having a threshold voltage lower than the read voltage Vread and maintained in bit lines coupled to memory cells having a threshold voltage higher than the read voltage Vread, among memory cells of the source page 110SP.

The second page buffer group 150B senses the voltages of the bit lines BL1 to BLk of the second memory plane 110B and stores data ‘1’ or data ‘0 depending on the result of the sense. When the voltage of a bit line is discharged, data ‘1’ may be stored, and when the voltage of the bit line remains intact, data ‘0’ may be stored. Thus, the data stored in the source page 110SP of the selected memory block 110MB is latched in the second page buffer group 150B.

Next, the data latched in the second page buffer group 1508 is transferred to the first page buffer group 150A. An exemplary transfer operation is described in detail below.

The coupling circuit 180 couples the bit lines BL1 to BLk of the second memory plane 110B and the bit lines BL1 to BLk of the first memory plane 110A in response to the coupling signal CBPGM of the control circuit 120. Next, the second page buffer group 150B outputs the data to the bit lines BL1 to BLk of the second memory plane 110B. The first page buffer group 150A stores the data received from the second page buffer group 150B through the bit lines BL1 to BLk of the second memory plane 110B and the bit lines BL1 to BLk of the first memory plane 110A. Next, the coupling circuit 180 disconnects the bit lines BL1 to BLk of the second memory plane 11013 from the bit lines BL1 to BLk of the first memory plane 110A in response to the coupling signal CBPGM of the control circuit 120.

Next, a program operation for a target page 110TP of the first memory plane 110B is performed. An exemplary program operation is described in detail below.

First, after the bit lines BL1 to BLk of the first and the second memory planes 110A and 110B are disconnected from each other in response to the coupling signal CBPGM generated by the control circuit 120, the first page buffer group 150A controls the voltages of the bit lines BL1 to BLk of the first memory plane 110A by using the data. For example, a page buffer in which data ‘1’ is latched may supply a program inhibition voltage (e.g., a power supply voltage) to a bit line coupled thereto, and a page buffer in which data ‘0’ is latched may supply a program permission voltage (e.g., a ground voltage) to a bit line coupled thereto. The voltage supply circuit (130 and 140A) supplies a selected memory block 110MB of the first memory plane 110A with the operating voltages including the program voltage Vpgm and the pass voltage Vpass. Here, the program voltage Vpgm is supplied to a word line corresponding to the target page 110TP, and the pass voltage Vpass is supplied to the remaining word lines of the selected memory block 110MB. In the target page 110TP, the threshold voltages of memory cells coupled to the bit line to which the program inhibition voltage has been supplied are not shifted although the program voltage Vpgm is supplied to the bit line, so that data ‘1’ is stored in the page buffer coupled to the bit line. Furthermore, the threshold voltages of memory cells coupled to the bit line to which the program permission voltage has been supplied rise up to at least a target level by the program voltage Vpgm, so that data ‘0’ is stored in the page buffer coupled to the bit line.

As described above, the data read from the source page 110SP of the second memory plane 110B is stored in the target page 110TP of the first memory plane 110A through only the bit lines BL1 to BLk and the first and the second page buffer groups 150A and 150B. Another embodiment of a data copyback operation is described below.

Referring to FIGS. 1 and 4B, a read operation for a source page 110SP is performed. An exemplary read operation is described in detail below.

First, the coupling circuit 180 couples the bit lines BL1 to BLk of the first memory plane 110A and the respective bit lines BL1 to BLk of the second memory plane 110B in response to the coupling signal CBPGM of the control circuit 120. The second page buffer group 150B precharges the bit lines BL1 to BLk of the second memory plane 110B through the bit lines BL1 to BLk of the first memory plane 110A.

The voltage supply circuit (130 and 140B) supplies a selected memory block 110MB of the second memory plane 110B with the operating voltages including the read voltage Vread and the pass voltage Vpass. Here, the read voltage Vread is supplied to a word line corresponding to the source page 110SP, and the pass voltage Vpass is supplied to the remaining word lines of the selected memory block 110MB. A voltage (i.e., a precharged voltage) is discharged from bit lines coupled to memory cells having a threshold voltage lower than the read voltage Vread and maintained in bit lines coupled to memory cells having a threshold voltage higher than the read voltage Vread, among memory cells of the source page 110SP.

The first page buffer group 150A senses the voltages of the bit lines BL1 to BLk of the second memory plane 110B through the bit lines BL1 to BLk of the first memory plane 110A and stores data ‘1’ or data ‘0’ depending on the result of the sense. When the voltage of a bit line is discharged, data ‘1’ may be stored, and when the voltage of the bit line remains intact, data ‘0’ may be stored. Thus, the data stored in the source page 110SP of the second memory plane 110B is latched in the first page buffer group 150A.

After the read operation of the source page 110SP is completed, the coupling circuit 180 disconnects the bit lines BL1 to BLk of the second memory plane 110B from the bit lines BL1 to BLk of the first memory plane 110A in response to the coupling signal CBPGM of the control circuit 120.

Next, a program operation for the target page 110TP is performed. The program operation of the target page 110TP may be performed like the program operation described with reference to FIG. 4A.

As described above, the first page buffer group 150A stores the data, read from the source page 110SP of the second memory plane 110B, in the target page 110TP of the first memory plane 110A through only the bit lines BL1 to BLk of the first and the second memory planes 110A and 110B.

Yet another embodiment of a data copyback operation is described below.

Referring to FIGS. 1 and 4C, the second page buffer group 150B performs a read operation of reading data from a source page 110SP of the second memory plane 110B. Next, the coupling circuit 180 couples the bit lines BL1 to BLk of the first and the second memory planes 110A and 110B so that the second page buffer group 150B may be coupled to the first memory plane 110A through the bit lines BL1 to BLk. Next, the second page buffer group 150B performs a program operation of storing the data, read from the source page 110SP of the second memory plane 110B, in a target page 110TP of the first memory plane 110A.

Meanwhile, after the data read from the source page 110SP is stored in the second page buffer group 150B, the control circuit 120 may generate the coupling signal CBPGM so that the coupling circuit 180 couples the bit lines BL1 to BLk of the first and the second memory planes 110A and 110B.

As described above, in accordance with the present disclosure, operational efficiency may be increased by a copyback operation of storing data, read from a source page of one memory plane, in a target page of the other memory plane.

What is claimed is:

1. A semiconductor memory device, comprising:
first and second memory planes that each comprise a plurality of memory blocks;
a first page buffer group coupled to the memory blocks of the first memory plane through first bit lines and configured to perform a read operation and a program operation;
a second page buffer group coupled to the memory blocks of the second memory plane through second bit lines and configured to perform the read operation and the program operation;
a coupling circuit configured to couple the first bit lines of the first memory plane and the second bit lines of the second memory plane, respectively, in response to a coupling signal; and
a control circuit configured to generate the coupling signal for controlling the coupling circuit in a copyback operation for storing data, read from a source page of the first memory plane, in a target page of the second memory plane.

2. The semiconductor memory device of claim 1, wherein:
the first page buffer group performs the read operation of reading the data from the source page of the first memory plane,
the coupling circuit transfers the data of the source page, stored in the first page buffer group, to the second page buffer group, and
the second page buffer group performs the program operation of storing the data in the target page of the second memory plane.

3. The semiconductor memory device of claim 2, wherein the control circuit controls the coupling circuit so that the first bit lines are disconnected from the second bit lines when the second page buffer group performs the program operation.

4. The semiconductor memory device of claim 2, wherein after the data read from the source page is stored in the first page buffer group, the control circuit generates the coupling signal so that the coupling circuit couples the first bit lines of the first memory planes and the second bit lines of the second memory planes.

5. The semiconductor memory device of claim 1, wherein:
the coupling circuit couples the first bit lines and the second bit lines so that the second page buffer group is coupled to the first memory plane through the first bit lines,
the second page buffer group performs the read operation of reading the data from the source page of the first memory plane, and
the second page buffer group performs the program operation of storing the data, read from the source page of the first memory plane, in the target page of the second memory plane.

6. The semiconductor memory device of claim 5, wherein the control circuit controls the coupling circuit so that the first bit lines are disconnected from the second bit lines when the second page buffer group performs the program operation.

7. The semiconductor memory device of claim 5, wherein the second page buffer group precharges the first bit lines of the first memory plane through the second bit lines in order to read the data from the source page of the first memory plane.

8. The semiconductor memory device of claim 1, wherein:
the first page buffer group performs the read operation of reading the data from the source page of the first memory plane,
the coupling circuit couples the first bit lines and the second bit lines so that the first page buffer group is coupled to the second memory plane through the second bit lines, and
the first page buffer group performs the program operation of storing the data, read from the source page of the first memory plane, in the target page of the second memory plane.

9. The semiconductor memory device of claim 8, wherein after the data read from the source page is stored in the first page buffer group, the control circuit generates the coupling signal so that the coupling circuit couples the first bit lines of the first memory planes and the second bit lines of the second memory planes.

10. The semiconductor memory device of claim 2, wherein the control circuit controls the read operation and the program operation.

11. The semiconductor memory device of claim 1, wherein the coupling circuit comprises switching elements coupled between the first bit lines and the second bit lines and configured to couple the first and the second bit lines, respectively, in response to the coupling signal.

12. The semiconductor memory device of claim 1, further comprising:
a voltage generator configured to generate operating voltages for reading the data from the source page or storing the data in the target page;
a first row decoder configured to transfer the operating voltages to the first memory plane in response to a first row address signal in order to read the data from the source page; and
a second row decoder configured to transfer the operating voltages to the second memory plane in response to a second row address signal in order to store the data in the target page.
